(19) United States
(12) Patent Application Publication
(10) Pub. No.: US 2012/0241718 A1
(43) Pub. Date: Sep. 27, 2012

(54) HIGH PERFORMANCE LIGHT EMITTING DIODE

(75) Inventors: Shiue-Lung Chen, Taoyuan County (TW); Wei-Chi Lee, Taoyuan County (TW); Chang-Ho Chen, Taoyuan County (TW)

(73) Assignee: WALSIN LIHWA CORPORATION, Taoyuan County (TW)

(21) Appl. No.: 13/398,703

(22) Filed: Feb. 16, 2012

Related U.S. Application Data
(60) Provisional application No. 61/455,000, filed on Mar. 21, 2011.

(51) Int. Cl. H01L 33/06

(52) U.S. Cl. 257/13; 257/E33.008

(57) ABSTRACT

A vertical light emitting diodes (LEDs) with new construction for reducing the current crowding effect and increasing the light extraction efficiency (LEE) of the LEDs is provided. By providing at least one current blocking portion corresponded to an electrode, the current flows from the electrode may be diffused or distributed more laterally instead of straight downward directly under the electrode and the current crowding effect could be reduced thereby. By providing at least one current blocking portion covered by a mirror layer to form an omni-directional reflective (ODR) structure, the internal light of the LEDs may be reflected by the ODR structure and the LEE could be increased thereby.

### BACKGROUND OF THE INVENTION

1. Field of the Invention

This invention relates generally to light emitting diodes (LEDs), and in particular, it relates to the vertical LEDs.

2. Description of Related Art

In recent years solid-state lighting devices such as semiconductor LEDs have become increasingly popular in illumination applications. This is largely attributable to the fact that newer LEDs are made more reliable with higher brightness, lower costs and better energy efficiency.

Typically, the light of a semiconductor LED is produced from an active layer of band-gap materials between a positively doped layer (p-layer) and a negatively doped layer (n-layer). When current is applied to the LED through its electrodes, the carriers, i.e., electrons from the n-layer and holes from the p-layer recombine in the active region, releasing energy in the form of photons, to produce light.

A widely used semiconductor material for LEDs is gallium nitride (GaN) compound. The GaN compound is a popular choice for making LEDs because of its high thermal stability and large energy band-gap width can be controlled by adjusting the composition.

An LED is often construed in one of two basic configurations, i.e., a vertical configuration where its electrodes are positioned on opposite sides of the substrate of the LED and a lateral configuration where its electrodes are positioned on the same side of the substrate. As compared to lateral GaN LEDs, vertical GaN LEDs that have advantages of less current crowding effect, larger effective area for light extraction, and lower series resistance are more suitable for the application of high power LEDs, especially in the situation of high current injection. Vertical GaN LEDs with the high heat conducting substrate (such as Cu, Si or AN material) by the wafer-bonding or the electroplating process have a huge opportunity in future LED lighting applications.

Currently the areas of improvement for vertical structure LEDs focus on reducing the current crowding effect under the electrode and increasing the efficiency of light extraction. It would be preferable to provide an LED construction that can reduce the current crowding effect and increase the light extraction efficiency (LEE) of the LED.

### SUMMARY

The following summary extracts and compiles some of the features of the present invention, while other features will be disclosed in the follow-up detailed descriptions of the invention. It is intended to cover various modifications and similar arrangements included within the spirit and scope of the appended claims.

The present invention is directed to a construction of LEDs, especially to a construction of vertical LEDs.

It is an object of the present invention to provide a vertical LED with a new construction that can reduce the current crowding effect and increase the LEE of the LED. The vertical LED comprises a lower electrode, a multi-semiconductor layer and an upper electrode. The multi-semiconductor layer has a lower surface, an upper surface, and at least one current blocking portion. The multi-semiconductor layer is positioned on the lower electrode and the upper electrode opposite to the lower electrode is positioned on the upper surface of the multi-semiconductor layer. The at least one current blocking portion is configured on the lower surface and corresponded to the upper electrode.

It is to be understood that both the foregoing general description and the following detailed description are exemplary and explanatory and are intended to provide further explanation of the invention as claimed.

### BRIEF DESCRIPTION OF THE DRAWINGS

FIG. 1 illustrates a cross-sectional view of a vertical LED according to an embodiment of the present invention.

FIG. 2a illustrates a cross-sectional view of a vertical LED according to another embodiment of the present invention.

FIG. 2b illustrates a cross-sectional view of a vertical LED according to still another embodiment of the present invention.

FIG. 3a illustrates a cross-sectional view of a vertical LED according to a further embodiment of the present invention.

FIG. 3b illustrates a top view of the n-sided electrode pad and its branch scheme of the embodiment of the present invention shown in FIG. 3a.

FIG. 3c illustrates a bottom view of the p-sided ODR structures of the embodiment of the present invention shown in FIG. 3a (without showing the substrate and seed layer, for clarity purpose).

FIG. 4a illustrates a cross-sectional view of a vertical LED according to a further embodiment of the present invention.

FIG. 4b illustrates a cross-sectional view of a vertical LED according to still a further embodiment of the present invention.

FIG. 5a illustrates a cross-sectional view of part of vertical LED according to the further embodiment of the present invention shown in FIG. 4a or FIG. 4b.

FIG. 5b illustrates a cross-sectional view of part of vertical LED according to the further embodiment of the present invention shown in FIG. 4a or FIG. 4b.

FIG. 5c illustrates a cross-sectional view of part of vertical LED according to the further embodiment of the present invention shown in FIG. 4a or FIG. 4b.

FIG. 5d illustrates a cross-sectional view of part of vertical LED according to the further embodiment of the present invention shown in FIG. 4a or FIG. 4b.

FIG. 6a illustrates a cross-sectional view of another part of vertical LED according to the further embodiment of the present invention shown in FIG. 4a or FIG. 4b.

FIG. 6b illustrates a cross-sectional view of another part of vertical LED according to the further embodiment of the present invention shown in FIG. 4a or FIG. 4b.

FIG. 6c illustrates a cross-sectional view of another part of vertical LED according to the further embodiment of the present invention shown in FIG. 4a or FIG. 4b.

FIG. 6d illustrates a cross-sectional view of another part of vertical LED according to the further embodiment of the present invention shown in FIG. 4a or FIG. 4b.

FIG. 6e illustrates a cross-sectional view of another part of vertical LED according to the further embodiment of the present invention shown in FIG. 4a or FIG. 4b.

FIG. 6f illustrates a cross-sectional view of another part of vertical LED according to the further embodiment of the present invention shown in FIG. 4a or FIG. 4b.

### DETAILED DESCRIPTION OF PREFERRED EMBODIMENTS

Embodiments of the present invention provide a new construction for LEDs, especially for vertical LEDs.

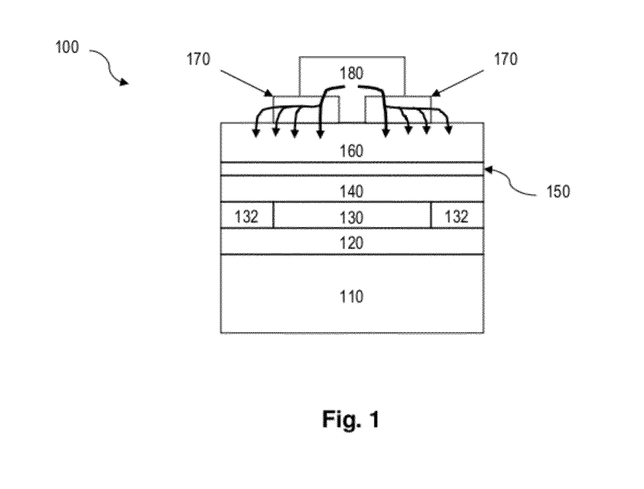

Referring to FIG. 1, there is shown a cross-sectional view of a vertical LED according to an embodiment of the present invention, which is characterized by utilizing a current blocking portion of metal materials such as Ni, Pt, Au, Pd, etc. that are easier to form barrier at the surface of n-GaN layer, and also combining with low work function materials such as TiN, CrN, Al, etc. that can form an ohmic-contact to the n-GaN layer, to reduce the current crowding effect and increase the LEE of the LED.

As shown in FIG. 1, the vertical LED 100 has a substrate 110, a seed layer 120, a p-mirror layer 130 attached to the substrate 110 by the seed layer 120 and protected by an insolated sidewall 132 made of, for example, SiO2 or SiN. A p-GaN layer 140 and an n-GaN layer 160 is provided on top of the p-mirror layer 130, sandwiching and separating by a multi-quantum-wells (MQW) active layer 150. On top of the n-GaN layer 160, there are provided an electrode in the form of a metal pad 180 made of high work function metals, for example, Ni, Pt, Au, which are easier to form or cause current blocking to the n-GaN layer 160. Further provided between the metal pad 180 and the n-GaN layer 160 are n-mirrors 170 which partially cover the metal pad 180 and are made of highly reflective materials such as TiNAl, CrNAl, AlNiAu, AlTiAu, creating an ohmic-contact to the n-GaN layer 160. The reflective material may be further supplemented with reflective metal layer made of, for example, Ag, Al, etc. With the construction that combine highly reflective minor layer and current blocking metal alloys, the injection current flows from the electrode 180 to the n-GaN layer 160, as indicated by the dark arrows in FIG. 1, are diffused or distributed more laterally instead of straight downward directly under the electrode, thereby reduces the current crowding effect.

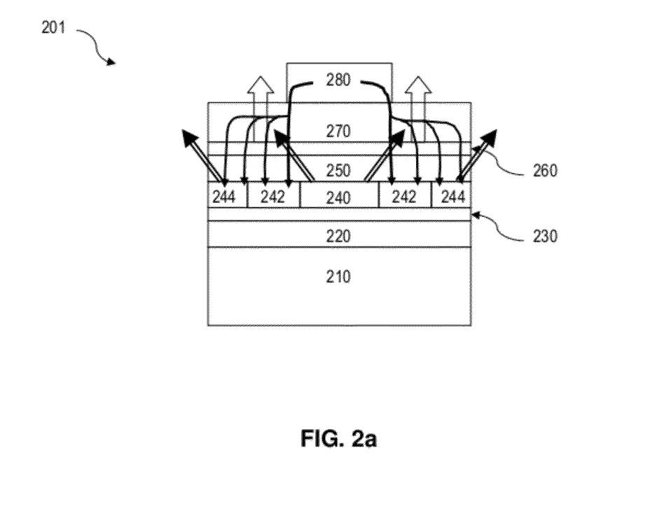

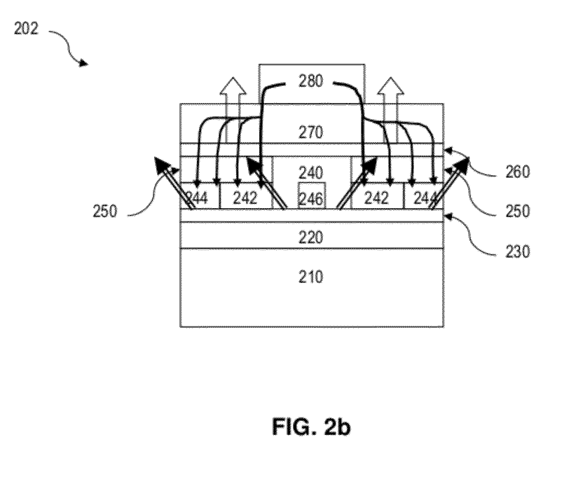

Referring to FIG. 2a, there is shown a cross-sectional view of a vertical LED according to another embodiment of the present invention, which is characterized by utilizing a deposit-type current blocking portion of oxide materials such as SiO₂, TiO₂, Ta₂O₃, Ta₂O₅, ZrO₂, HfO₂, etc. or oxide compounds such as SiO₂/TiO₂, SiO₂/Ta₂O₃, SiO₂/Ta₂O₅, SiO₂/ZrO₂, SiO₂/HfO₂, etc., followed by utilizing p-mirror reflective materials such as Ag, Ag alloys, NiAg alloys, NiAgAl alloys, NiAl alloys, etc. that can form an ohmic-contact to the p-GaN layer, and further utilizing low refractive materials such as a SiO₂ layer to match with the high reflective metal to form an ODR structure, to reduce the current crowding effect and increase the LEE of the LED.

As shown in FIG. 2a, the vertical LED 201 has a substrate 210, a seed layer 220, and a reflective layer 230 attached to the substrate 210 by the seed layer 220. A deposit-type current blocking portion 240 is provided above the reflective layer 230. The current blocking portion 240 has a top part made of insulated material such as SiO₂ and a bottom part made of metal reflective material such as Ag, Al. The thickness of the insulated top part is selected to be an integer multiple of λ/4n, where λ is the wavelength of the light and n is the refractive index of the insulated material. The two-part current blocking portion 240 provides an ODR structure. Also provided above the reflective layer 230 is a p-mirror layer 242 protected by an insolated sidewall 244 made of, for example, SiO₂/TiO₂, SiO₂/Ta₂O₃, SiO₂/Ta₂O₅, SiO₂/ZrO₂, or SiO₂/HfO₂ compound. The reflective layer 230 and the p-mirror layer 242 may be made of metal materials such as Ag, Ag alloys, Al, Al alloys. The current blocking portion 240, p-mirror layer 242 and insolated sidewall 244 form multiple ODR structures above the reflective layer 230. Further, a p-GaN layer 250 and an n-GaN layer 270 are provided on the top of the current blocking portion 240, p-mirror layer 242 and insolated sidewall 244, which are separated by an MQW layer 260. Ohmic-contact is formed between the p-mirror layer 242 and the p-GaN layer 250. Finally, a metal pad electrode 280 is provided above the n-GaN layer 270. The design and construction of the metal pad electrode 280 can be similar to the metal pad electrode 180 described above. With the construction that also combine highly reflective minor layer and current blocking metal alloys, the current flows from the electrode 280, as indicated by the dark arrows in FIG. 2a, are diffused or distributed more laterally instead of straight downward directly under the electrode, thereby reduces the current crowding effect. This construction of the vertical LED 201 also increases the LEE of both the main light as indicated by the white block-arrows and the side light as indicated by the double-line black arrows, from reflection by the ODR structures and the metal reflective layers described above.

Referring to FIG. 2b, there is shown a cross-sectional view of a vertical LED according to still another embodiment of the present invention, which is characterized by utilizing an embedded-type current blocking portion of oxide materials such as SiO₂, TiO₂, Ta₂O₃, Ta₂O₅, ZrO₂, HfO₂, etc. or oxide compounds such as SiO₂/TiO₂, SiO₂/Ta₂O₃, SiO₂/Ta₂O₅, SiO₂/ZrO₂, SiO₂/HfO₂, etc., followed by utilizing p-mirror reflective materials such as Ag, Ag alloys, NiAg alloys, NiAgAl alloys, NiAl alloys, etc. that can form an ohmic-contact to the p-GaN layer, and further utilizing low refractive materials such as SiO₂ to match with the high reflective metal to form an ODR structure, to reduce the current crowding effect and increase the LEE of the LED.

As shown in FIG. 2b, the vertical LED 201 has a substrate 210, a seed layer 220, and a reflective layer 230 attached to the substrate 210 by the seed layer 220. An embedded-type CBL 240 is provided above the reflective layer 230.

A p-mirror 246 is embedded within the current blocking portion 240. The current blocking portion 240 may be made of insulated material such as SiO₂ and the p-mirror 246 may be made of metal reflective material such as Ag, Al. The thickness of the current blocking portion 240 is selected to be an integer multiple of λ/4n, where λ is the wavelength of the light and n is the refractive index of the insulated material. Also provided above the reflective layer 230 is an other p-mirror layer 242 made of metal material such as Ag, Ag alloys, Al, Al alloys, protected by an insolated sidewall 244 made of, for example, SiO₂/TiO₂, SiO₂/Ta₂O₃, SiO₂/Ta₂O₅, SiO₂/ZrO₂, or SiO₂/HfO₂ compound. Furthermore, a p-GaN layer 250 is provided above the other p-mirror layer 242 and insolated sidewall 244, and surrounds the current blocking portion 240. Ohmic-contact is formed between the other p-mirror layer 242 and p-GaN layer 250. The current blocking portion 240, the p-mirror 246, the other p-mirror layer 242 and insolated sidewall 244 form multiple ODR structures above the reflective layer 230. An MQW layer 260 is provided above the p-GaN layer 250 and the current blocking portion 240. An n-GaN layer 270 is further provided above the MQW layer 260. Lastly, a metal pad electrode 280 is provided above the n-GaN layer 270. The design and construction of the metal pad electrode 280 can be similar to the metal pad electrode 180 described above. With the construction that again combine highly reflective minor layer and current blocking metal alloys, the current flows from the electrode 280, as indicated by the dark arrows in FIG. 2b, are diffused or distributed more laterally instead of straight downward directly under the electrode, thereby reduces the current crowding effect. This construction of the vertical LED 202 also increases the LEE of both the main light as indicated by the white block-arrows and the side light as indicated by the double-line black arrows, from reflection by the ODR structures and the metal reflective layers described above.

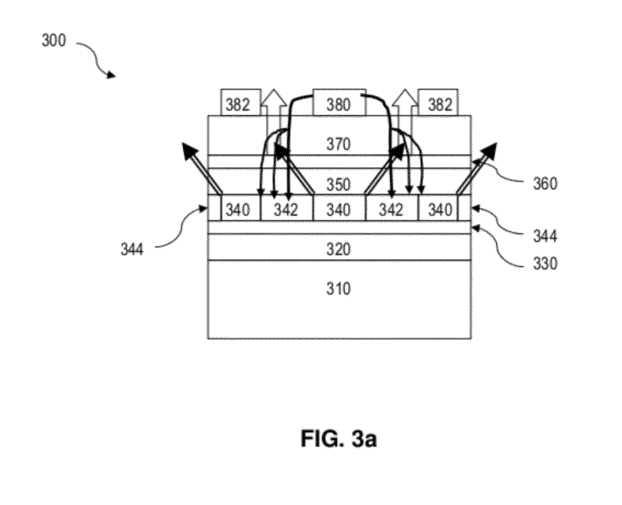

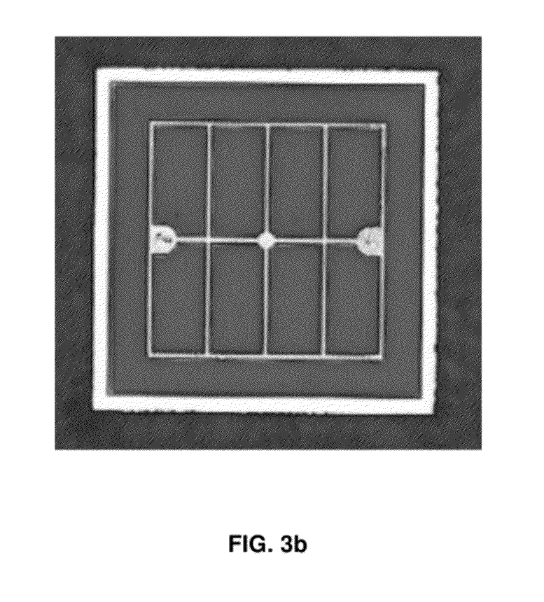

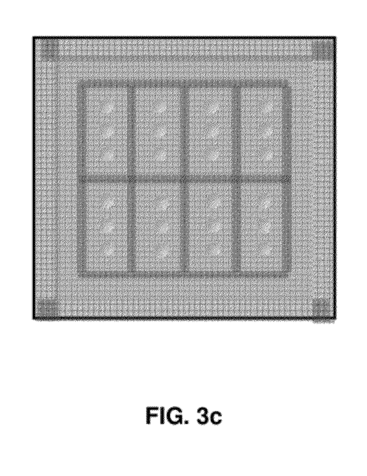

Referring to FIG. 3a, there is shown a cross-sectional view of a vertical LED according to a further embodiment of the present invention, which is characterized by utilizing multiple current blocking portions of oxide materials such as SiO₂, TiO₂, Ta₂O₃, Ta₂O₅, ZrO₂, HfO₂, etc. or oxide compounds such as SiO₂/TiO₂, SiO₂/Ta₂O₃, SiO₂/Ta₂O₅, SiO₂/ZrO₂, SiO₂/HfO₂, etc., followed by utilizing reflective materials such as Ag, Ag alloys, NiAg alloys, NiAgAl alloys,

NiAl alloys, etc. for the p-mirror layer to form an ohmic-contact to the p-GaN layer, and further utilizing low refractive materials such as SiO₂ to match with the high reflective metal to form an ODR structure, to reduce the current crowding effect and increase the LEE of the LED.

As shown in FIG. 3a, the vertical LED 300 has a substrate 310, a seed layer 320, and a reflective layer 330 attached to the substrate 310 by the seed layer 320. Multiple current blocking portions 340 are provided above the reflective layer 330. At least one of the current blocking portions 340 has a top part made of insulated material such as SiO₂ and a bottom part made of metal reflective material such as Ag, Al. The thickness of the insulated top part is selected to be an integer multiple of λ/4n, where λ is the wavelength of the light and n is the refractive index of the insulated material. The two-part current blocking portion 340 provides an ODR structure. Also provided above the reflective layer 330 is a p-mirror layer 342 protected by an insolated sidewall 344 made of, for example, SiO₂/TiO₂, SiO₂/Ta₂O₃, SiO₂/Ta₂O₅, SiO₂/ZrO₂, or SiO₂/HfO₂, compound. The reflective layer 330 and the p-mirror layer 342 may be made of metal materials such as Ag, Ag alloys, Al, Al alloys. The current blocking portions 340, p-mirror layer 342 and insolated sidewall 344 form multiple ODR structures above the reflective layer 330. Further, a p-GaN layer 350 and an n-GaN layer 370 are provided above the current blocking portions 340, p-mirror layer 342 and insolated sidewall 344, which are separated by an MQW layer 360. Ohmic-contact is formed between the p-mirror layer 342 and the p-GaN layer 350. Finally, a metal pad electrode 382 and its branches 380 are provided above the n-GaN layer 370. With the construction that also combine highly reflective mirror layer and current blocking metal alloys, the current flows from the electrode 310, as indicated by the dark arrows in FIG. 3a, are diffused or distributed more laterally instead of straight downward directly under the electrode, thereby reduces the current crowding effect. This construction of the vertical LED 300 also increases the LEE of both the main light as indicated by the white block-arrows and the side light as indicated by the double-line black arrows, from reflection by the ODR structures and the metal reflective layers described above.

Referring to FIG. 3b, there is shown a top view of the n-side electrode pad and its branches scheme of the embodiment according to the present invention shown in FIG. 3a. In addition to the center metal pad, metal electrode branches are added to further reduces the current crowding effect.

Referring to FIG. 3c, there is shown a bottom view of the p-side ODR structures of the embodiment according to the present invention shown in FIG. 3a (without showing the substrate and seed layer, for clarity purpose). Multiple ODR structures (shown as the small round dots) made of insulated and reflective materials, for example, SiO₂ and Ag, are formed in the current blocking portion on the p-mirror side to further increase the LEE of the LED.

The preferred embodiments of present invention, as shown exemplarily in the figures described below, for deducing current crowding and improving light extraction of the vertical LED.

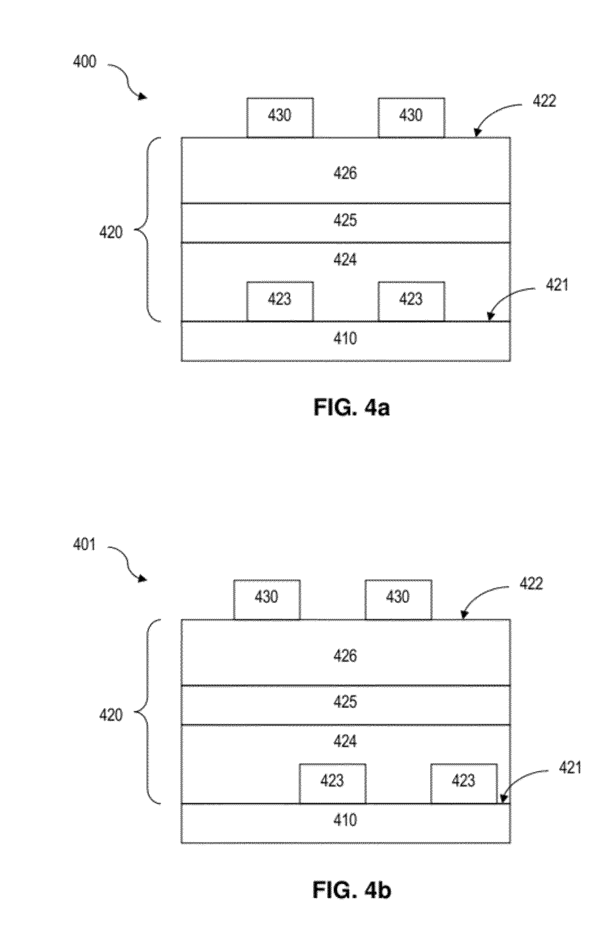

Referring to FIG. 4a, there is illustrated a cross-sectional view of a vertical LED according to a further embodiment of the present invention, where an upper electrode and current blocking portions above a lower electrode are vertically aligned.

As shown in FIG. 4a, the vertical LED 400 has a lower electrode 410, a multi-semiconductor layer 420, and an upper electrode 430. The multi-semiconductor layer 420 has a lower surface 421, an upper surface 422, and at least one current blocking portion 423 configured on the lower surface 421. The lower surface 421 is connected to the lower electrode 410 and the upper electrode 430 opposite to the lower electrode 410 is positioned on the upper surface 422. The at least one current blocking portion 423 is configured on the lower surface 421 and corresponded to the upper electrode 430. In this embodiment, the at least one current blocking portion 423 is aligned with the upper electrode 430, but not limited thereto. In other embodiments, the at least one current blocking portion may be offset with the upper electrode. In one embodiment, the upper electrode may have a main portion and at least one extension portion extended from the main portion. The materials of the lower electrode 410 and the upper electrode 430 may be selected from TiN, CrN, TiNAlNiAu, or TiNAgNiAu, respectively.

The multi-semiconductor layer 420 further comprises a lower semiconductor layer 424, a multi-quantum-wells active layer 425, and an upper semiconductor layer 422. More specifically, the lower semiconductor layer 424 is positioned on the lower electrode 410 and has the lower surface 421 and the at least one current blocking portion 423. The multi-quantum-wells active layer 425 is positioned on the lower semiconductor layer 424. The upper semiconductor layer 426 is positioned on the multi-quantum-wells active layer 425 and has the upper surface 422. In other embodiments, each of the lower semiconductor layer and the upper semiconductor layer may comprise a plurality of layers. In this embodiment, the lower semiconductor layer 424 is a p-type semiconductor layer and the upper semiconductor layer 426 is an n-type semiconductor layer, but not limited thereto. In other embodiments, the lower semiconductor layer 424 may be an n-type semiconductor layer and the upper semiconductor layer 426 may be a p-type semiconductor layer.

Referring to FIG. 4b, there is illustrated a cross-sectional view of a vertical LED 401 according to still a further embodiment of the present invention, where the upper electrode 430 and the at least one current blocking portion 423 above the lower electrode 410 are vertically offset.

As described before, with the construction that at least one current blocking portion 423 corresponds to the upper electrode 430, the current flows (not shown) from the upper electrode 430 are diffused or distributed more laterally instead of straight downward directly, and the current crowding effect could be reduced and the LEE also could be increased thereby.

The possible modifications and variations of the preferred embodiments will be further described as follows.

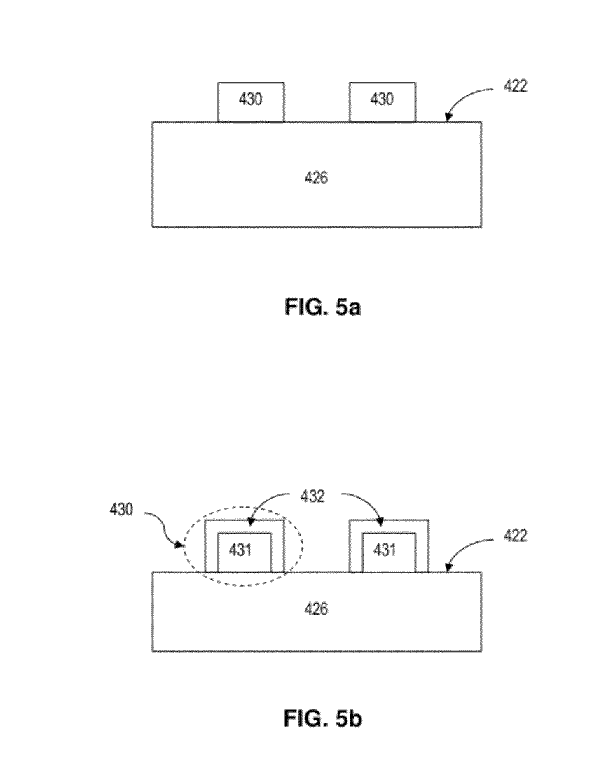

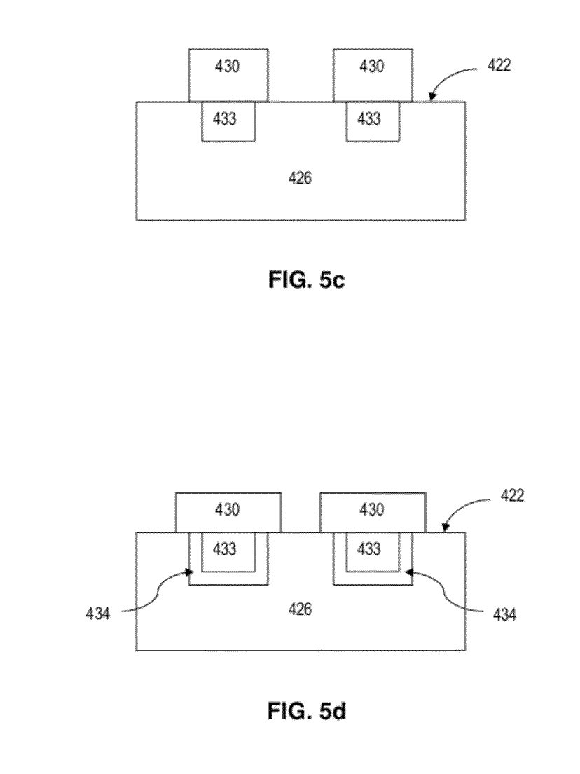

Referring to FIG. 5a, there is illustrated a cross-sectional view of part of vertical LED 400 or 401 according to the present invention shown in FIG. 4a or FIG. 4b. In this embodiment, the upper electrode 430 is a metal pad, but not limited thereto. In other embodiments, the upper electrode 430 may be at least one current blocking portion 431 covered by a mirror layer 432 to form an ODR structure, as shown in FIG. 5b.

Referring to FIG. 5c, there is illustrated a cross-sectional view of part of vertical LED 400 or 401 according to the present invention shown in FIG. 4a or FIG. 4b. In this embodiment, the upper electrode 430 is a metal pad, and the upper semiconductor layer 426 further comprises at least one current blocking portion 431 configured underneath the upper electrode 430. In other embodiments, the at least one current blocking portion 431 may be further covered by a mirror layer 434 to form an ODR structure, as shown in FIG. 5d.

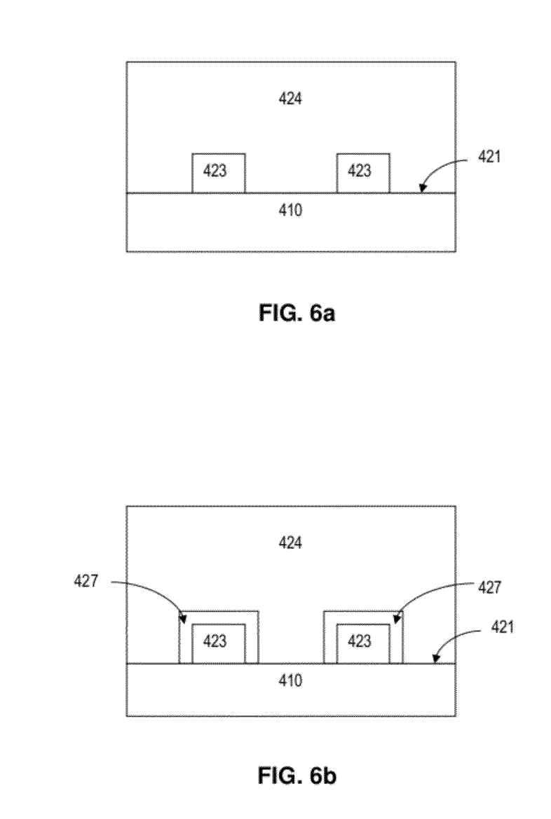

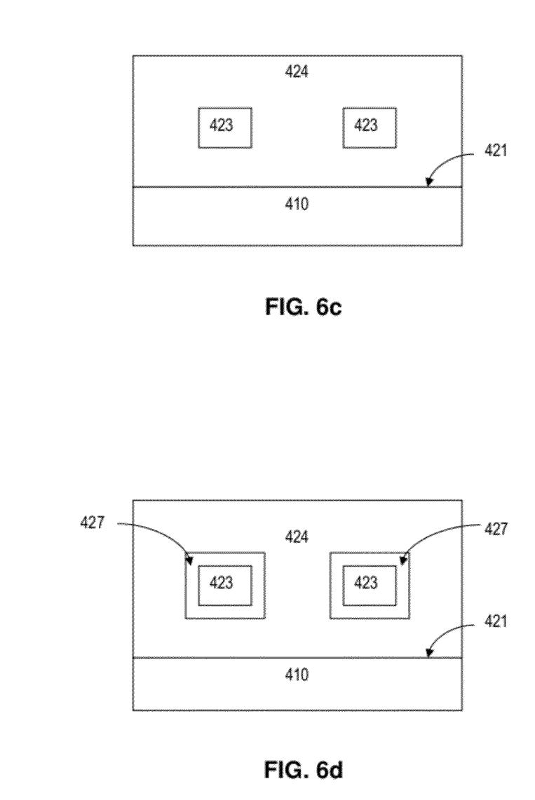

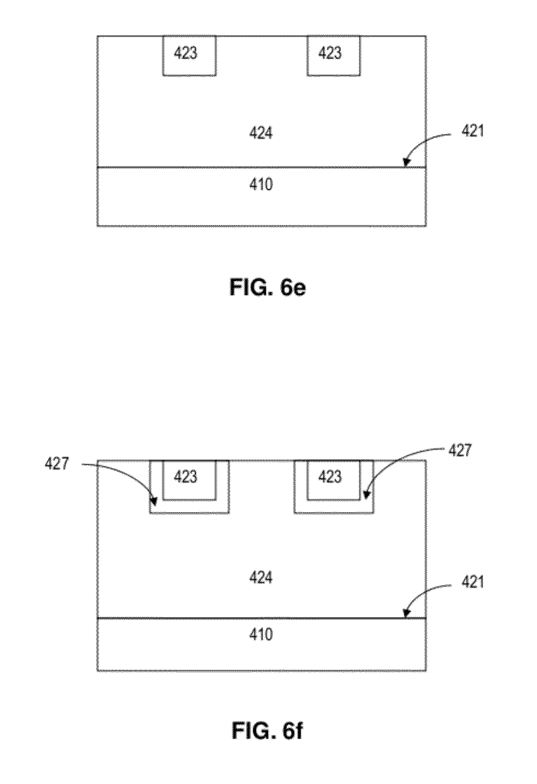

Referring to FIG. 6a, there is illustrated a cross-sectional view of part of vertical LED 400 or 401 according to the present invention shown in FIG. 4a or FIG. 4b. In this embodiment, the lower semiconductor layer 424 has at least one current blocking portion 423 positioned at the bottom of the lower semiconductor layer 424, but not limited thereto. In other embodiments, the at least one current blocking portion 423 may be positioned in the middle of the lower semiconductor layer 424 or at the top of the lower semiconductor layer 424, as shown in FIG. 6c and FIG. 6e, respectively. Moreover, the at least one current blocking portion 423 may be further covered by a mirror layer 427, as shown in FIG. 6b, FIG. 6d and FIG. 6f.

More specifically, the materials of the current blocking portions 423, 431 and 433 may be selected from oxide materials such as SiO₂, TiO₂, Ta₂O₃, Ta₂O₅, ZrO₂, HfO₂, etc. or oxide compounds such as SiO₂/TiO₂, SiO₂/Ta₂O₃, SiO₂/Ta₂O₅, SiO₂/ZrO₂, SiO₂/HfO₂, etc., respectively. The materials of the mirror layers 427, 432 and 434 may be selected from reflective materials such as Ag, Ag alloys, NiAg alloys, NiAgAl alloys, NiAl alloys, etc., or other materials with high reflective index, respectively.

The vertical LEDs according to the present invention have the advantages as follows:
(1) By providing at least one current blocking portion corresponded to the electrode according to the present invention, the current flows from the electrode may be diffused or distributed more laterally, and the current crowding effect could be reduced thereby.
(2) By providing at least one current blocking portion covered by a minor layer to form an ODR structure, the internal light of the vertical LEDs may be reflected by the ODR structure and the LEE could be increased thereby.

While the present invention has been described in terms of what is presently considered to be the most practical and preferred embodiment, it is understood that the invention needs not be limited to the disclosed embodiments. To the contrary, it is intended to cover various modifications, variations and similar arrangements included within the spirit and scope of the appended claims and their equivalents, which are to be accorded with the broadest interpretation so as to encompass all such modifications and similar structures. It will be apparent to those skilled in the art that such modification, variations and arrangements can be made to the designs and constructions according to the present invention without departing from the spirit or scope of the invention.

What is claimed is:

1. A vertical light emitting diode (LED), comprising:
a lower electrode;
a multi-semiconductor layer positioned on the lower electrode, having an upper surface, a lower surface, and at least one current blocking portion configured on the lower surface; and
an upper electrode opposite to the lower electrode positioned on the upper surface, the at least one current blocking portion is corresponded to the upper electrode.

2. The vertical LED according to claim 1, wherein the upper electrode is aligned with the at least one current blocking portion.

3. The vertical LED according to claim 1, wherein the upper electrode is offset with the at least one current blocking portion.

4. The vertical LED according to claim 1, wherein the upper electrode is a metal pad.

5. The vertical LED according to claim 1, wherein the upper electrode has a current blocking portion covered by a mirror layer to form an omni-directional reflective (ODR) structure.

6. The vertical LED according to claim 1, wherein the upper electrode is a metal pad with an underneath current blocking portion.

7. The vertical LED according to claim 1, wherein the upper electrode is a metal pad with an underneath current blocking portion which is covered by a mirror layer to form an omni-directional reflective (ODR) structure.

8. The vertical LED according to claim 5 or claim 7, wherein the material of the mirror layer is selected from Ag, Ag alloys, Al, Al alloys, NiAg, NiAl, or other materials having high reflective index.

9. The vertical LED according to claim 1, wherein the materials of the lower electrode and the upper electrode are selected from TiN, CrN, TiNAlNiAu, or TiNAgNiAu, respectively.

10. The vertical LED according to claim 1, wherein the multi-semiconductor layer comprises:
a lower semiconductor layer positioned on the lower electrode, having the lower surface and the at least one current blocking portion;
a multi-quantum-wells active layer positioned on the lower semiconductor layer; and
an upper semiconductor layer positioned on the multi-quantum-wells active layer, having the upper surface.

11. The vertical LED according to claim 10, wherein the at least one current blocking portion is positioned at the bottom of the lower semiconductor layer.

12. The vertical LED according to claim 10, wherein the at least one current blocking portion is positioned in the middle of the lower semiconductor layer.

13. The vertical LED according to claim 10, wherein the at least one current blocking portion is positioned at the top of the lower semiconductor layer.

14. The vertical LED according to claim 10, wherein the at least one current blocking portion is covered by respective minor layers to form omni-directional reflective (ODR) structures.

15. The vertical LED according to claim 14, wherein the material of the respective mirror layers is selected from Ag, Ag alloys, Al, Al alloys, NiAg, NiAl, or other materials having high reflective index.

16. The vertical LED according to claim 10, wherein the lower semiconductor layer is a p-type semiconductor layer and the upper semiconductor layer is an n-type semiconductor layer.

17. The vertical LED according to claim 10, wherein the lower semiconductor layer is an n-type semiconductor layer and the upper semiconductor layer is a p-type semiconductor layer.

18. The vertical LED according to claim 1, wherein the upper electrode having a main portion and at least one extension portion extended form the main portion.
